(19) United States
(12) Patent Application Publication
(10) Pub. No.: US 2016/0027624 A1
(43) Pub. Date: Jan. 28, 2016

(54) SPUTTERING APPARATUS

(71) Applicant: CANON ANELVA CORPORATION, Kawasaki-shi (JP)

(72) Inventors: Susumu KARINO, Tokyo (JP); Masahiro SHIBAMOTO, Tokyo (JP)

(73) Assignee: CANON ANELVA CORPORATION, Kawasaki-shi (JP)

(21) Appl. No.: 14/792,946

(22) Filed: Jul. 7, 2015

(30) Foreign Application Priority Data
Jul. 24, 2014 (JP) 2014-151007

(51) Int. Cl. H01J 37/34

(52) U.S. Cl. CPC H01J 37/3455; H01J 37/3488; H01J 37/3435

(57) ABSTRACT

A sputtering apparatus that forms a film on a substrate by sputtering in a chamber includes an electrode including a holding portion that holds a target, and configured to apply a potential to the target via the holding portion, a first magnet and second magnet arranged to sandwich a space between the holding portion, and a substrate arrangement surface on which the substrate should be arranged, and to be spaced apart from each other in a direction along the substrate arrangement surface, a shield arranged between the first magnet and the second magnet, and between the substrate arrangement surface and the holding portion, and a rotation driving unit configured to integrally rotate the target, the first magnet, and the second magnet.

### BACKGROUND OF THE INVENTION

1. Field of the Invention

The present invention relates to a sputtering apparatus.

2. Description of the Related Art

Japanese Patent Laid-Open No. 2005-48227 discloses a box type facing target sputtering apparatus including a pair of targets arranged to face each other so as to sandwich a space facing one surface of a substrate to be processed. A permanent magnet is arranged on the rear surface side of each target, and a cooling jacket is arranged between the target and the permanent magnet. Each target is built up together with a portion constituting the cooling jacket, the permanent magnet, and the like, thereby constituting a target unit. Each target unit is fixed to a frame.

In the box type facing target sputtering apparatus disclosed in Japanese Patent Laid-Open No. 2005-48227, the pair of targets is stationarily arranged, so a film formed on the substrate tends to be nonuniform. In addition, in the box type facing target sputtering apparatus disclosed in Japanese Patent Laid-Open No. 2005-48227, each of the paired target units needs to be attached to the frame. Moreover, each target unit is large in size because it includes the portion constituting the cooling jacket, the permanent magnet, and the like in addition to the target. Therefore, the box type facing target sputtering apparatus disclosed in Japanese Patent Laid-Open No. 2005-48227 is considered to require a long time for maintenance such as exchange of the target. In the arrangement in which the cooling jacket is arranged between the permanent magnet and the target, a magnetic field generated by the permanent magnet is attenuated by a coolant in the cooling jacket or the like. Thus, the permanent magnet needs to be upsized.

### SUMMARY OF THE INVENTION

The present invention provides a sputtering apparatus that is advantageous for reducing in-plane variations of a film deposited on a substrate.

One of aspects of the present invention provides a sputtering apparatus that forms a film on a substrate by sputtering in a chamber, comprising: an electrode including a holding portion that holds a target, and configured to apply a potential to the target via the holding portion; a first magnet and second magnet arranged to sandwich a space between the holding portion, and a substrate arrangement surface on which the substrate should be arranged, and to be spaced apart from each other in a direction along the substrate arrangement surface; a shield arranged between the first magnet and the second magnet, and between the substrate arrangement surface and the holding portion; and a rotation driving unit configured to integrally rotate the target, the first magnet, and the second magnet.

Further features of the present invention will become apparent from the following description of exemplary embodiments with reference to the attached drawings.

### BRIEF DESCRIPTION OF THE DRAWINGS

FIG. 1 is a plan view schematically showing the arrangement of a processing system according to one embodiment of the present invention;

FIG. 2 is a sectional view showing the arrangement of a deposition apparatus;

FIG. 3 is a sectional view showing the arrangement of the deposition apparatus;

FIG. 4 is a sectional view showing the arrangement of the deposition apparatus;

FIGS. 5A and 5B are views showing one arrangement example of a target; and

FIGS. 6A and 6B are views showing another arrangement example of a target.

### DESCRIPTION OF THE EMBODIMENTS

An exemplary embodiment of the present invention will now be described with reference to the accompanying drawings.

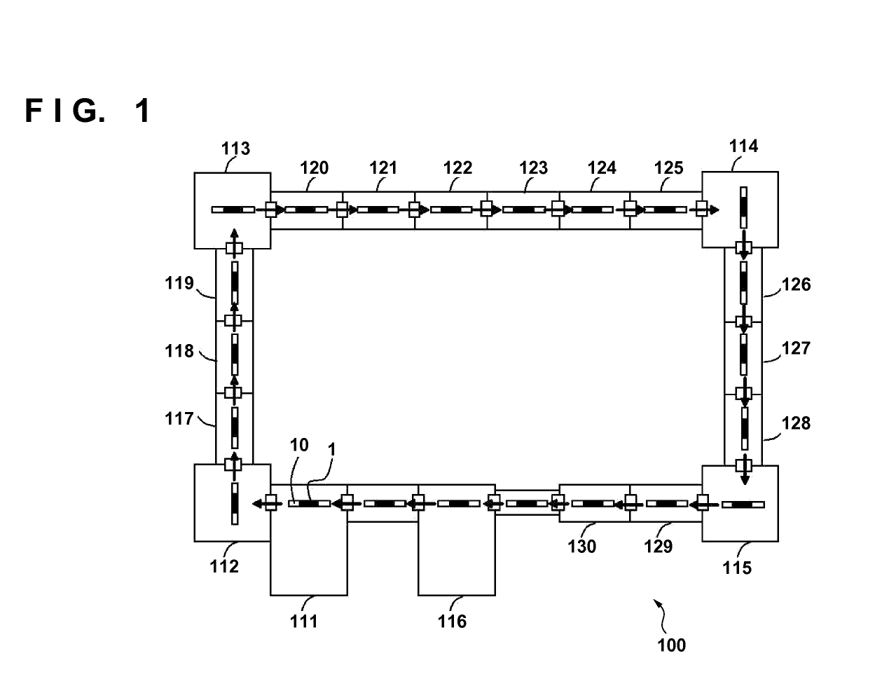

FIG. 1 is a plan view schematically showing the arrangement of a processing system 100 according to one embodiment of the present invention. The processing system 100 is constituted as an inline type processing apparatus. The inline type is a type in which a substrate is processed while being conveyed through a plurality of connected chambers. In the processing system 100 shown in FIG. 1, a plurality of chambers 111 to 130 are endlessly connected to constitute a rectangular layout. Each of the chambers 111 to 130 includes a conveyance device that conveys a substrate 1 held by a carrier 10. Chambers adjacent to each other out of the chambers 111 to 130 are connected via gate valves. The chamber 111 is a load lock chamber in which processing of attaching the substrate 1 to the carrier 10 is performed. The chamber 116 is an unload lock chamber in which processing of detaching the substrate 1 from the carrier 10 is performed.

More specifically, an example in which the processing system 100 is applied to a processing apparatus for manufacturing a hard disk will be explained. The substrate 1 can be, for example, a metal or glass disk-shaped member having a hole at the center portion. The carrier 10 can be configured to hold two substrates.

First, two unprocessed substrates 1 are attached to the first carrier 10 in the chamber 111. The carrier 10 moves to the chamber 117 for forming a contact layer, and contact layers are formed on the substrates 1. Meanwhile, two unprocessed substrates 1 are attached to the second carrier 10.

Then, soft magnetic layers are formed on the substrates 1 while the first carrier 10 sequentially moves to the chambers 118, 119, and 120 for forming a soft magnetic layer. Meanwhile, the second carrier 10 moves to the chamber 117 for forming a contact layer, and contact layers are formed on the substrates 1. Further, in the chamber 111, the substrates 1 are attached to the third carrier 10. In this manner, every time the preceding carrier 10 and the succeeding carrier 10 move, the substrates 1 are attached to the subsequent carrier 10 in the chamber 111.

The first carrier 10 holding the substrates 1, on each of which the soft magnetic layer is formed, moves to the chamber 121 for forming a seed layer, and seed layers are formed on the substrates 1. After that, the first carrier 10 sequentially moves to the chambers 123 and 124 for forming an intermediate layer, the chambers 126 and 127 for forming a magnetic film, and the chamber 129 for forming a protective film.

The chambers 112, 113, 114, and 115 are arranged at the four corners of the rectangular layout. Each of the chambers 112, 113, 114, and 115 includes a direction change device that changes the conveyance direction of the carrier 10 (substrate 1) by 90°.

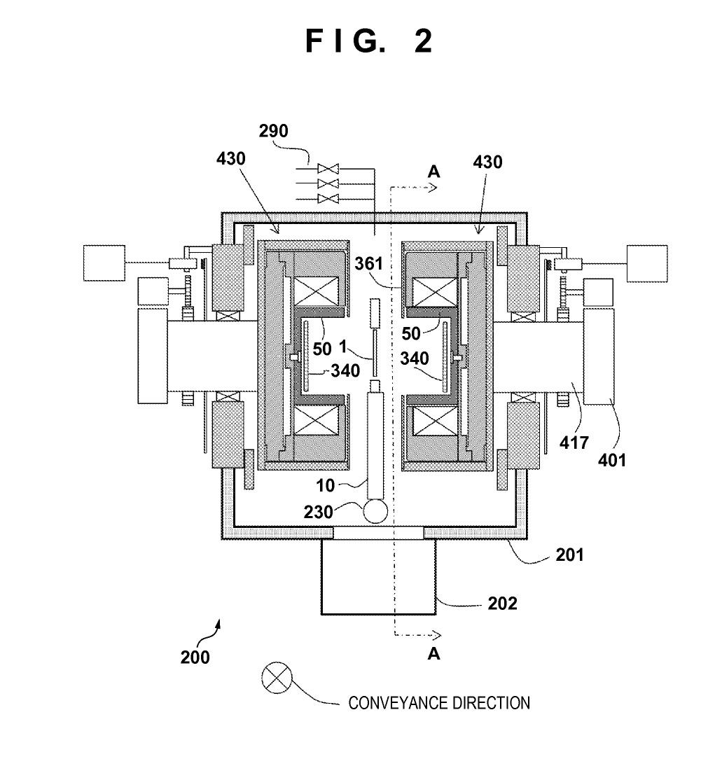

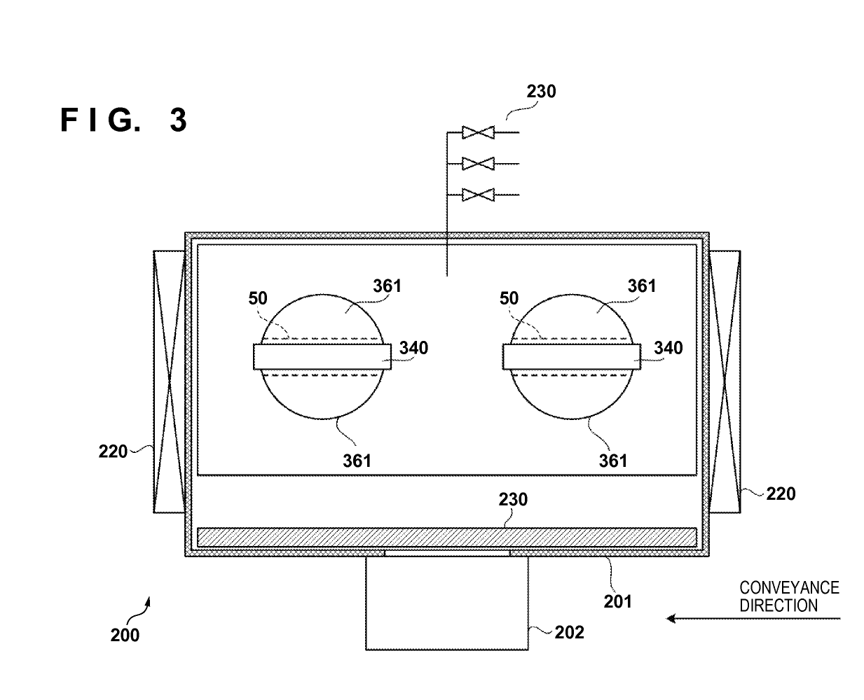

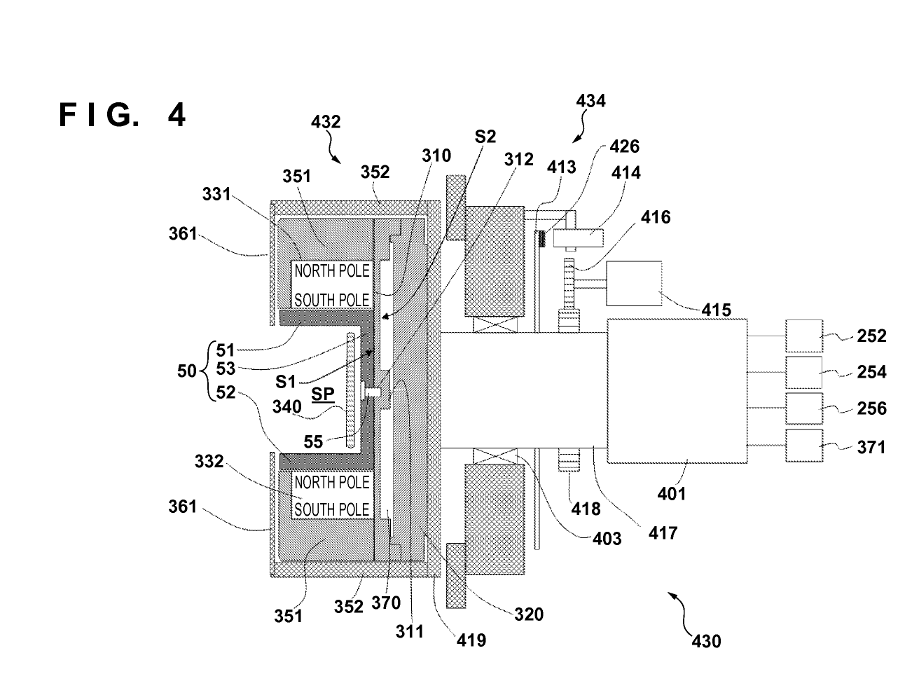

The chambers 117 to 130 (excluding the chambers 112 to 114) are building components of the deposition apparatus, respectively. FIGS. 2 and 3 are views showing the arrangement of one deposition apparatus. Each of the chambers 117 to 130 (excluding the chambers 112 to 114) corresponds to a chamber 201 in FIG. 2. FIG. 2 is a sectional view showing the deposition apparatus 200 taken along a plane (plane along the conveyance direction) perpendicular to the conveyance direction of the carrier 10 (substrate 1). FIG. 3 is a sectional view (sectional arrow view) taken along a line A-A′ in FIG. 2. FIG. 4 shows the arrangement of a cathode unit 430 that holds and drives a target (sputtering target) 50. The deposition apparatus 200 is constituted as a sputtering apparatus.

The deposition apparatus (sputtering apparatus) 200 includes the chamber 201, a conveyance device 230 that conveys the carrier 10, and gate valves 220 arranged on the upstream and downstream sides of the conveyance path of the carrier 10 by the conveyance device 230. The chamber 201 is connected to adjacent chambers via the gate valves 220.

The deposition apparatus 200 includes a gas supply unit 290 and an exhaust device 202. The gas supply unit 290 supplies gas into the chamber 201, and the exhaust device 202 exhausts the gas in the chamber 201, thereby controlling the internal pressure of the chamber 201 to a target pressure.

In this embodiment, films are simultaneously formed by sputtering on the two surfaces of each of the two substrates 1 in the chamber 201. In the chamber 201, four targets 50 are arranged. More specifically, the first target 50 faces one surface of the first substrate, the second target 50 faces the other surface of the first surface, the third target 50 faces one surface of the second substrate, and the fourth target 50 faces the other surface of the second substrate. Each of the first to fourth targets 50 is held and driven by one cathode unit 430. Note that the deposition apparatus 200 may be configured to form films on only one substrate 1 in one chamber 201.

As exemplified in FIG. 4, the cathode unit 430 includes an electrode unit 432 and a rotation driving unit 434. The electrode unit 432 can include, as its building components, an electrode (cathode) 310 serving as a backing plate, a first magnet 331, a second magnet 332, a first shield 340, second shields 361, and third shields 352. The electrode 310 includes a holding portion 311 that holds the target 50. The electrode 310 is configured to apply a potential to the target 50 via the holding portion 311. The electrode 310 can receive a potential from a power supply 371 via, for example, a base member 320 and the rotation driving unit 434. The power supply 371 can be, for example, a pulse DC power supply, but may be another power supply. The shield 340 can receive a potential from a power supply 252 via the rotation driving unit 434. The shields 361 and 352 can receive a potential from a power supply 254 via the rotation driving unit 434. The rotation driving unit 434 has a structure for integrally rotating the building components of the electrode unit 432. The rotation driving unit 434 will be described later.

The first magnet 331 and the second magnet 332 can be constituted by, for example, permanent magnets. The first magnet 331 and the second magnet 332 are arranged to sandwich a space SP between the holding portion 311, and a substrate arrangement surface on which the substrate 1 should be arranged, and to be spaced apart from each other in a direction along the substrate arrangement surface. The shield 340 is arranged between the first magnet 331 and the second magnet 332, and between the substrate arrangement surface SS and the holding portion 311.

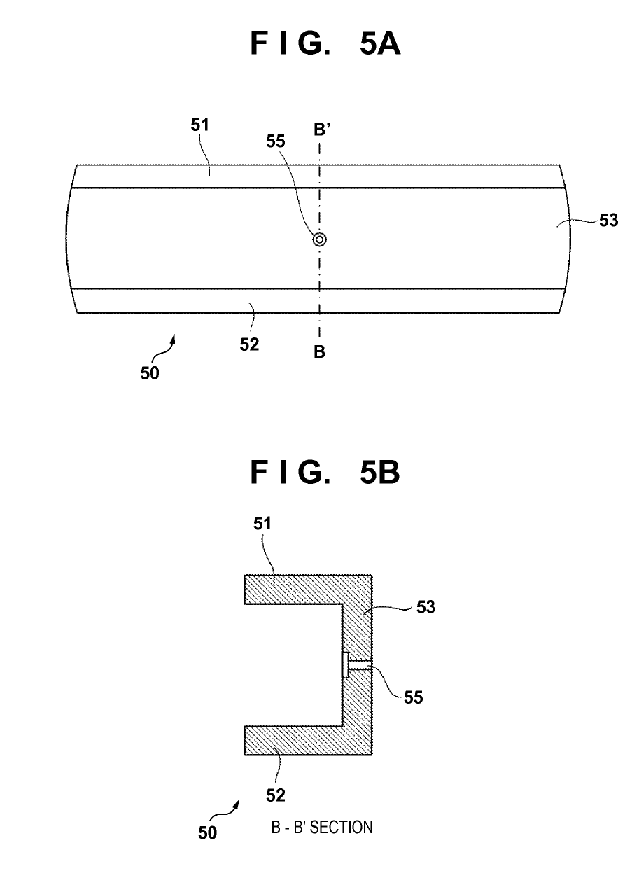

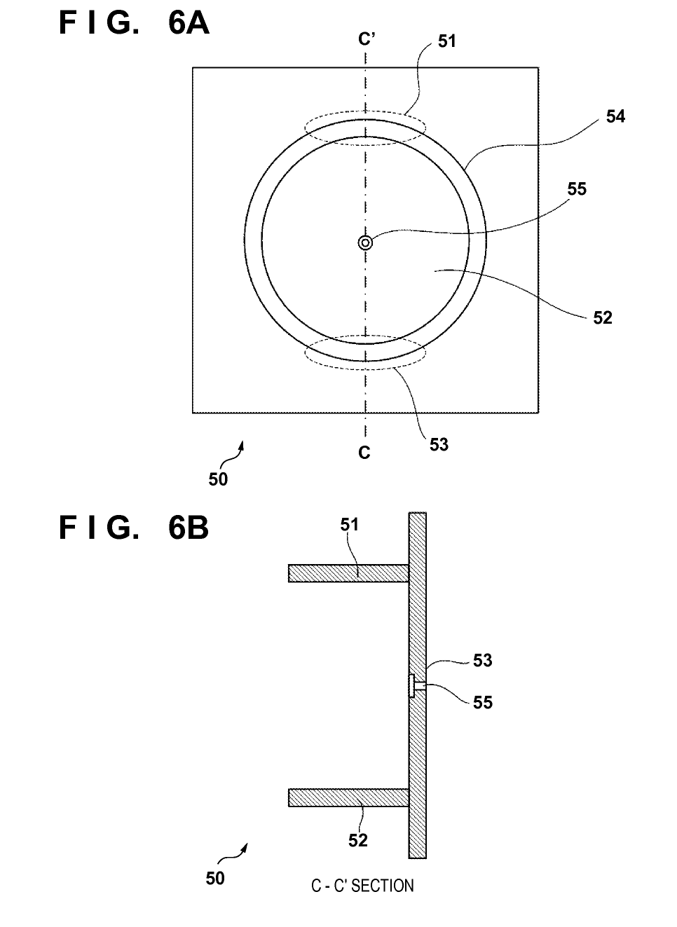

As exemplified in FIGS. 5A and 5B or FIGS. 6A and 6B, the target 50 includes a first portion 51 that should be arranged between the first magnet 331 and the space SP, a second portion 52 that should be arranged between the second magnet 332 and the space SP, and a connecting portion 53 that connects the first portion 51 and the second portion 52. The connecting portion 53 of the target 50 is fixed to the holding portion 311. The holding portion 311 includes an engaging portion 312 with which a fixing member 315 for fixing the target 50 is engaged. For example, the engaging portion 312 is a threaded hole, and the fixing member 315 is a screw. The fixing member 315 extends through a hole 55 formed in the connecting portion 53 of the target 50, and is screwed into the engaging portion 312. The first portion 51 and second portion 52 receive a potential from the electrode 310 via the connecting portion 53.

The structure in which the target 50 is supported by holding the connecting portion 53, out of the first portion 51, second portion 52, and connecting portion 53 of the target 50, by the holding portion 311 of the electrode 310 is advantageous for facilitating the work of mounting the target 50 on the electrode 310 and dismounting the target 50 from the electrode 310.

FIGS. 5A and 5B show one arrangement example of the target 50. As exemplified in FIGS. 5A and 5B, the first portion 51 and second portion 52 of the target 50 can be parallel to each other. Each of the first portion 51 and second portion 52 of the target 50 can have a flat plate shape. In the space between the first portion 51 and the second portion 52, a magnetic field having an orientation from the first portion 51 to the second portion 52 or from the second portion 52 to the first portion 51 is formed.

FIG. 4 exemplifies the magnetic poles of the first magnet 331 and second magnet 332. In the example shown in FIG. 4, the first magnet 331 is arranged so that the south pole faces the discharge space SP, and the second magnet 332 is arranged so that the north pole faces the discharge space SP. That is, in the example shown in FIG. 4, the south pole of the first magnet 331 and the north pole of the second magnet 332 face each other to form a magnetic field whose orientation coincides with a direction perpendicular to surfaces of the first portion 51 and second portion 52 that face each other. Note that the first magnet 331 and the second magnet 332 may be arranged so that the north pole of the first magnet 331 and the south pole of the second magnet 332 face each other, in contrast to the example shown in FIG. 4.

A uniform magnetic field can be formed in the discharge space SP by forming a magnetic field whose orientation coincides with the direction perpendicular to surfaces of the first portion 51 and second portion 52 of the target 50 that face each other. The uniform magnetic field in the discharge space SP has an effect of suppressing redeposition on the target 50.

FIGS. 6A and 6B show another arrangement example of the target 50. As exemplified in FIGS. 6A and 6B, the first portion 51 and second portion 52 of the target 50 can be portions facing each other at a cylindrical portion 54.

The first portion 51, second portion 52, and connecting portion 53 are preferably made of the same material integrally. However, it is also possible to make the first portion 51 and second portion 52 from the same material (target material such as carbon), and make the connecting portion 53 from a material different from that of the first portion 51 and second portion 52. In this case, the connecting portion 53 should be formed from a material excellent in electrical conductivity and thermal conductivity for the purpose of efficient cooling of the first portion 51 and second portion 52 and efficient potential supply to the first portion 51 and second portion 52.

Further, the first portion 51 and second portion 52 may be made of different materials. In this case, films of different materials are formed on the substrate 1, that is, co-sputtering is implemented.

The shield 340 can receive a potential capable of preventing sputtering of the connecting portion 53 of the target 50, for example, a ground potential. The shield 340 is arranged at an interval from the connecting portion 53 to prevent a short circuit with the connecting portion 53.

A positive potential may be applied to the shield 340. By applying a positive potential to the shield 340, ions of the positive potential between the first portion 51 and the second portion 52 can be pushed toward the substrate 1. To the contrary, a neutral particle is not influenced by the potential of the shield 340. When the target 50 is made of carbon, deposition of carbon ions can be performed more efficiently. The substrate 1 at the time of deposition can be set to be a floating potential.

The holding portion 311 has a first surface S1 for holding the target 50, and a second surface S2 opposite to the first surface S1. The deposition apparatus 200 can include, on the side of the second surface S2 of the holding portion 311, a cooling channel 370 for cooling the electrode 310. The cooling channel 370 is formed between the electrode 310 (holding portion 311) and the base member 320. The first portion 51 and second portion 52 of the target 50 are cooled by cooling the connecting portion 53 of the target 50 via the holding portion 311 by a cooling medium flowing through the cooling channel 370.

It is preferable that the cooling channel through which the cooling medium flows is not provided between the first magnet 331 and the position at which the first portion 51 of the target 50 should be arranged, and between the second magnet 332 and the position at which the second portion 52 of the target 50 should be arranged. When no cooling channel is arranged between the first magnet 331 and the position at which the first portion 51 of the target 50 should be arranged, and between the second magnet 332 and the position at which the second portion 52 of the target 50 should be arranged, a magnetic field generated by the first magnet 331 and the second magnet 332 can be guided to the space SP with less attenuation. This is advantageous for downsizing the first magnet 331 and the second magnet 332.

The deposition apparatus 200 or the electrode unit 432 can further include the above-mentioned second shields 361 between the substrate arrangement surface SS, and the positions at which the first magnet 331 and the second magnet 332 are arranged, respectively. The deposition apparatus 200 or the electrode unit 432 can further include blocks 351 and the third shields 352. The blocks 351 can be arranged outside the first magnet 331 and the second magnet 332. The blocks 351 can be formed from, for example, aluminum. The third shields 352 can be arranged to surround the blocks 351, the electrode 310, and the base member 320. The third shields 352 can be electrically connected to the second shields 361. The second shields 361 and the third shields 352 can be grounded.

A discharge occurs in the space SP by applying a potential to the first portion 51 and second portion 52 of the target 50 from the power supply 371 via the electrode 310 while controlling the internal pressure of the chamber 201 to a target pressure by supplying gas from the gas supply unit 290 into the chamber 201 and exhausting the gas in the chamber 201 by the exhaust device 202. Resultantly generated ions sputter the first portion 51 and second portion 52 of the target 50. Particles flying out of the first portion 51 and second portion 52 of the target 50 form a film on the substrate 1.

The cathode unit 430 will be explained below. As described above, the cathode unit 430 includes the electrode unit 432 and the rotation driving unit 434. The electrode unit 432 can include the electrode (cathode) 310, the first magnet 331, the second magnet 332, the first shield 340, the second shields 361, the third shields 352, the base member 320, and a bottom plate 419.

The rotation driving unit 434 includes a rotation shaft 417 connected to the bottom plate 419, and a rotary joint 401 connected to the rotation shaft 417. A gear 418 is arranged around the rotation shaft 417. A gear 416 fixed to the rotation shaft of a motor 415 is engaged with the gear 418. A rotation force generated by the motor 415 is transferred to the rotation shaft 417 via the gears 416 and 418. Accordingly, the cathode unit 430 rotates together with the rotation shaft 417.

A magnetic seal 403 is provided between the rotation shaft 417 and an opening formed in the chamber 201. The gears 418 and 416, the motor 415, and the rotary joint 401 are arranged outside the chamber 201 (that is, on the air side).

The rotary joint 401 is provided to connect the electrode unit 432 and the power supplies 371, 252, and 254 and a temperature control unit 256 on the air side through the rotation shaft 417. The power supply 371 applies a potential to the electrode (cathode) 310 via the rotary joint 401 and the rotation shaft 417. The power supply 252 applies a potential to the first shield 340 via the rotary joint 401 and the rotation shaft 417. The power supply 254 applies a potential to the second shields 361 and the third shields 352 via the rotary joint 401 and the rotation shaft 417. The temperature control unit 256 supplies a cooling medium for temperature control to the cooling channel 370 via the rotary joint 401 and the rotation shaft 417. As the rotary joint 401, for example, a rotary joint disclosed in International Publication No. WO 2013/088603 can be employed.

A disk 413 is fixed to the rotation shaft 417, and the disk 413 and a sensor 414 can constitute an encoder. A black portion 426 is provided in a semicircular shape on a surface of the disk 413 on the side of the sensor 414. The rotation of the rotation shaft 417 (that is, the rotation of the electrode unit 432) is detected by detecting the black portion 426 by the sensor 414. The sensor 414 suffices to be able to discriminate the black portion 426 from the remaining portion (disk 413). For example, an FU-6F sensor available from KEYENCE is usable. Instead of this arrangement, an arrangement in which the rotation of the electrode unit 432 is detected by detecting a mark provided on the electrode unit 432 or the like may be employed.

According to this embodiment, in-plane variations of a film formed on the substrate 1 can be reduced by rotating the electrode unit 432. The target 50 including the first portion 51, second portion 52, and connecting portion 53, and the holding portion 311 holding the target 50 contribute to facilitating maintenance such as exchange of the target 50. The arrangement in which no cooling channel is arranged between the first magnet 331 and the first portion 51, and between the second magnet 332 and the second portion 52 is advantageous for decreasing the distance between the first magnet 331 and the first portion 51, and decreasing the distance between the second magnet 332 and the second portion 52. This contributes to downsizing the first magnet 331 and the second magnet 332.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-151007, filed Jul. 24, 2014, which is hereby incorporated by reference herein in its entirety.

What is claimed is:

1. A sputtering apparatus that forms a film on a substrate by sputtering in a chamber, comprising:
an electrode including a holding portion that holds a target, and configured to apply a potential to the target via the holding portion;
a first magnet and second magnet arranged to sandwich a space between the holding portion, and a substrate arrangement surface on which the substrate should be arranged, and to be spaced apart from each other in a direction along the substrate arrangement surface;
a shield arranged between the first magnet and the second magnet, and between the substrate arrangement surface and the holding portion; and
a rotation driving unit configured to integrally rotate the target, the first magnet, and the second magnet.

2. The apparatus according to claim 1, wherein power is supplied to the electrode via the rotation driving unit.

3. The apparatus according to claim 1, wherein a potential is supplied to the shield via the rotation driving unit.

4. The apparatus according to claim 1, wherein
the target includes a first portion that should be arranged between the first magnet and the space, a second portion that should be arranged between the second magnet and the space, and a connecting portion that connects the first portion and the second portion, and
the connecting portion is fixed to the holding portion.

5. The apparatus according to claim 4, wherein
the holding portion includes a first surface for holding the target, and a second surface opposite to the first surface,
the sputtering apparatus includes, on a side of the second surface of the holding portion, a cooling channel for cooling the electrode, and
the first portion and second portion of the target are cooled by cooling the connecting portion via the holding portion by a cooling medium flowing through the cooling channel.

6. The apparatus according to claim 5, wherein the cooling medium is supplied to the cooling channel via the rotation driving unit.

7. The apparatus according to claim 4, wherein the cooling channel through which the cooling medium flows is not provided between the first magnet and a position at which the first portion of the target should be arranged, and between the second magnet and a position at which the second portion of the target should be arranged.

8. The apparatus according to claim 4, wherein the first portion and the second portion have a flat panel shape, and are arranged to be parallel to each other.

9. The apparatus according to claim 8, wherein the first magnet and the second magnet are provided to form a magnetic field in a direction perpendicular to surfaces of the first portion and second portion that face each other.
